(19) United States
(12) Patent Application Publication
(10) Pub. No.: US 2015/0028933 A1
(43) Pub. Date: Jan. 29, 2015

(54) GATE DRIVING CIRCUIT FOR DISPLAY

(71) Applicant: Shyhfeng Chen, Shenzhen (CN)

(72) Inventor: Shyhfeng Chen, Shenzhen (CN)

(73) Assignee: Shenzhen China Star Optoelectronics Technology Co., Ltd., Shenzhen (CN)

(21) Appl. No.: 13/511,684

(22) PCT Filed: Apr. 5, 2012
(86) PCT No.: PCT/CN2012/073516

§ 371 Date: May 24, 2012

(30) Foreign Application Priority Data
Mar. 30, 2012 (CN) 201210091066.7

(51) Int. Cl. G09G 3/36; H03K 17/687; H03K 17/16

(52) U.S. Cl. CPC G09G 3/3648; H03K 17/162; H03K 17/6871; G09G 2320/0214
USPC 327/382

(57) ABSTRACT

A gate driving circuit for a display is disclosed. The gate driving circuit utilizes at least one transistor connected in series between an input end of a reference voltage signal and a transistor connected to a node providing a high voltage level for making the at least one transistor share the voltage difference between the source electrode and the drain electrode of the transistor connected to the node. In such a manner, the gate driving circuit can reduce the occurrence of current leakage in the transistor, thereby improving the stability of driving voltage of the gate driving circuit and the reliability of the gate driving circuit.

### TECHNICAL FIELD OF THE INVENTION

The present invention relates to a gate driving circuit of a display, and more particularly, to a gate driving circuit of a display capable of effectively reducing the occurrence of current leakage in transistors.

### BACKGROUND OF THE INVENTION

Liquid crystal displays (LCDs) may display an image by utilizing an electric field to alter the light transmittance of liquid crystal molecules having a dielectric anisotropy. The LCDs generally comprises a display panel having pixels arranged in a matrix and a driving circuit for driving the display panel.

The aforesaid driving circuit generally is divided into a source driving circuit and a gate driving circuit. The source driving circuit is utilized to transform the inputted data into data signals. The gate driving circuit will generate scan signals that are used to drive the pixels for displaying the image corresponding to the inputted data. The source driving circuit and the gate driving circuit are operated according to the sequence determined by a control signal that is generated from a clock controller.

Nowadays, in order to reduce the cost of displays, adopting thin-film amorphous-Si transistors to design the gate driving circuit of a LCD has gradually become the mainstream. However, thin-film amorphous-Si transistors may have a problem of threshold-voltage drift due to a long-time use or high bias voltage applied thereto, and this affects the stability of the driving circuit and causes the image quality degraded.

Generally, a traditional gate driving circuit is constructed by multi-stage shift registers connected in series. The gate pulse signal outputted from a shift register is also provided to a next-stage shift register as being an input signal. The related arts can refer to U.S. Pat. No. 7,825,887 and TW200813920.

FIG. 1 is a schematic diagram showing a part of a conventional gate driving circuit of a display. The gate driving circuit is utilized to generate pulse signals according to a predetermine sequence. The pulse signals are transmitted to gate lines to control thin-film transistors in the pixels of the display panel. As shown in FIG. 1, a transistor T11 serves as an initial switch and a transistor T12 serves as a pulse switch. When a start pulse signal ST turns on the transistor T11, a storage capacitor Cb will be charged. When a clock signal CLK is at a high voltage level, the storage capacitor Cb will be discharged, and thus a voltage signal V_{N} serving as an output signal OUT(N) is provided to a Nth gate line on the display panel.

The transistor T12 is usually called a pull-up transistor. Since it has to supply electricity to the entire gate line, the pull-up transistor must provide a large current. If the pull-up transistor T12 is unable to provide sufficient current, the pixels corresponding to the gate line may not function normally.

The transistor T13 and the transistor T14 serve as pull-down transistors which make the voltage signal transmitted to the gate line be pulled down to a voltage closer to the voltage level of a reference voltage signal Vss. Specifically, by using a reset signal RESET to turn on the transistor T13 and the transistor T14, the transistor T13 can make the voltage of a node Q1 be pulled down to a voltage closer to the voltage level of the reference voltage signal Vss and the transistor T14 can make the voltage of a node Q2 be pulled down to a voltage closer to the voltage level of the reference voltage signal Vss.

However, the gate driving circuit is easily to generate noise signals since it has to provide high voltage for the pull-up transistor T12. Therefore, it is necessary to add additional auxiliary noise suppressing circuits. There is an approach adopting transistors to suppress the noise signals in a digital signal processing. However, this approach needs much more transistors, occupies a larger layout area, and thus it is not suitable for the developments on narrow-board display products.

FIG. 2 is a schematic diagram showing a part of circuit utilized to suppress noise in a conventional gate driving circuit of a display. In order to reduce noise signals, the conventional gate driving circuit utilizes a coupled capacitor to suppress noise. In the equivalent circuit shown in FIG. 2, a coupled capacitor Cp is inserted between the clock signal CLK and a connecting terminal P1 of a transistor T21 and a transistor T22 such that it can use less number of transistors to suppress the noise signals, the layout area is relatively decreased, and thereby it is beneficial to the development on narrow-boarder display products.

However, in the circuit shown in FIG. 2, since the voltage of the node Q1 is pulled up to a voltage level that is twice of the clock signal CLK, the voltage Vds between the source electrode and the drain electrode of the transistor T21 is too high and this may cause current leakage. The voltage of the node Q1 will drop due to the current leakage of the transistor T21, and this may reduce driving ability of the gate driving circuit and make the pixels corresponding to the gate line unable to function normally.

### SUMMARY OF THE INVENTION

An objective of the present invention is to provide a gate driving circuit of a display, for solving the problem of current leakage, occurred in transistors of the gate driving circuit.

Another objective of the present invention is to provide a gate driving circuit of a display, for improving the stability of driving voltage of the gate driving circuit and the reliability of the gate driving circuit.

In an aspect, the present invention provides a gate driving circuit for a display, said circuit comprising: a first node having a voltage level when a start signal passes the first node; a first transistor coupled to the first node and an input end of a reference voltage signal, a voltage of the first node is pulled down to a voltage closer to the voltage of the reference voltage signal when the first transistor is turned on; a second transistor, of which one end is electrically connected to the first transistor and another end is electrically connected to the input end of the reference voltage signal; a second node located at a connecting terminal of the first transistor and the second transistor; a capacitor disposed between the second node and an input end of a clock signal, the first transistor, the second transistor, and the capacitor are utilized to suppress noise signals; and a third transistor disposed between the first transistor and the input end of the reference voltage signal, the third transistor is connected to the first transistor in series, the third transistor and the first transistor share a voltage difference between the first node and the input end of the reference voltage signal.

In the gate driving circuit of the present invention, a gate electrode of the first transistor is electrically connected to a gate electrode of the third transistor.

In the gate driving circuit of the present invention, said circuit further comprises a fourth transistor disposed between the third transistor and the input end of the reference voltage signal, the fourth transistor is connected to the third transistor in series, the fourth transistor, the third transistor, and the first transistor share the voltage difference between the first node and the input end of the reference voltage signal.

In the gate driving circuit of the present invention, a gate electrode of the third transistor is electrically connected to a gate electrode of the fourth transistor.

In the gate driving circuit of the present invention, a gate electrode of the second transistor is electrically connected to the first node.

In another aspect, the present invention provides a gate driving circuit for a display, said circuit comprising: a first transistor, a first end of the first transistor is coupled to a first node providing a high voltage level and a second end of the first transistor is coupled to an input end of a reference voltage signal; a second transistor, a first end of the second transistor is electrically connected to a third end of the first transistor and forms a second node therebetween, a second end of the second transistor is coupled to the input end of the reference voltage signal and a third end of the second transistor is coupled to the first node; a capacitor, of which one end is electrically connected to the second node located between the first transistor and the second transistor and the other end is electrically coupled to an input end of a clock signal; and at least one transistor disposed between the first transistor and the input end of the reference voltage signal, the at least one transistor is connected to the first transistor in series.

In the gate driving circuit of the present invention, the third end of the first transistor is a gate electrode and the gate electrode of the first transistor is electrically connected to the gate electrode of the at least one transistor.

In the gate driving circuit of the present invention, a voltage of the first node is pulled down to a voltage closer to the voltage of the reference voltage signal when the first transistor and the at least one transistor are turned on.

In the gate driving circuit of the present invention, the third end of the first transistor is a gate electrode and the first end of the second transistor is a source electrode or a drain electrode.

In the gate driving circuit of the present invention, the first transistor, the second transistor, and the at least one transistor are amorphous-Si transistors.

In yet another aspect, the present invention provides a gate driving circuit for a display, said circuit comprising: a first node for transmitting a driving signal of a high voltage level to an output terminal based on a start signal and a clock signal, the output terminal is electrically connected to a gate line; a first transistor, a first end of the first transistor is coupled to the first node and a second end of the first transistor is coupled to an input end of a reference voltage signal; a second transistor, a first end of the second transistor is electrically connected to a third end of the first transistor, a second end of the second transistor is coupled to the input end of the reference voltage signal, and a third end of the second transistor is coupled to the first node; a second node located at a connecting terminal of the first transistor and the second transistor; a capacitor, of which one end is electrically connected to the second node located between the first transistor and the second transistor and the other end is electrically coupled to an input end of the clock signal; and at least one transistor disposed between the first transistor and the input end of the reference voltage signal, the at least one transistor is connected to the first transistor in series.

In the gate driving circuit of the present invention, said circuit further comprises a start transistor disposed between an input end of the start signal and the first node; and a clock transistor disposed between the input end of the clock signal and the first node.

In the gate driving circuit of the present invention, said circuit further comprises a storage capacitor disposed between the first node and the output terminal.

In the gate driving circuit of the present invention, said circuit further comprises a first pull-down transistor disposed between the first node and the input end of the reference voltage signal; and a second pull-down transistor disposed between the output terminal and the input end of the reference voltage signal, wherein voltages of the first node and the output terminal are pulled down to the voltage of the reference voltage signal when the first pull-down transistor and the second pull-down transistor are turned on according to a reset signal.

By connecting the at least one transistor in series between the first transistor and the input end of the reference voltage signal, the present invention can partly transfer the voltage load between the source electrode and the drain electrode of the first transistor to the at least one transistor. In such a manner, the first transistor is unlikely to be affected by the high voltage on the first node so as to generate leakage current and make the voltage on the first node drop, lead to insufficient driving voltage. Therefore, the present invention can efficiently solve the problem of the stability of driving voltage of the gate driving circuit and improve the reliability of the gate driving circuit, thereby improving image quality of the display panel.

To make above content of the present invention more easily understood, it will be described in details by using preferred embodiments in conjunction with the appending drawings.

### BRIEF DESCRIPTION OF THE DRAWINGS

FIG. 1 is a schematic diagram showing a part of a conventional gate driving circuit of a display.

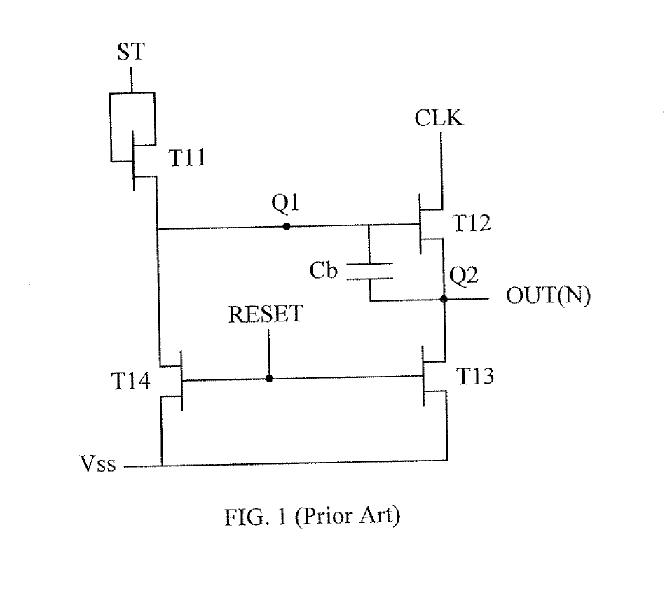

FIG. 2 is a schematic diagram showing a part of circuit utilized to suppress noise in a conventional gate driving circuit of a display.

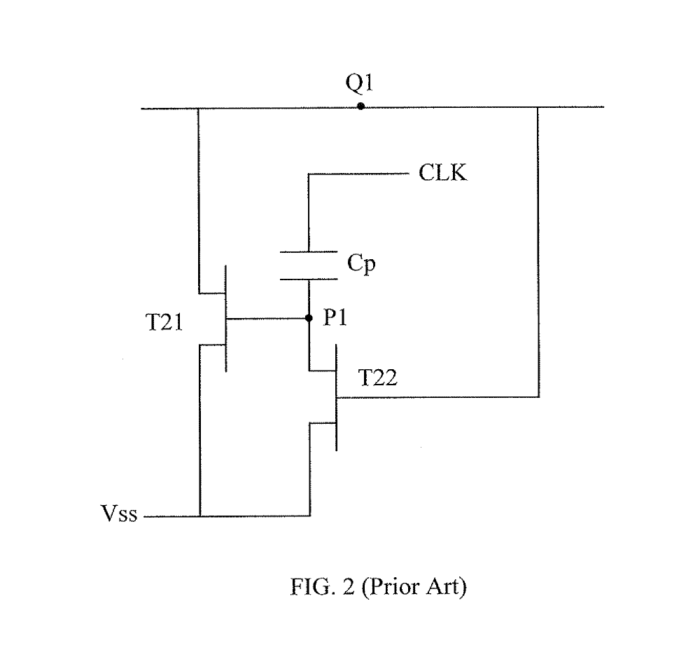

FIG. 3 is a schematic diagram showing a gate driving circuit of a display according to a first embodiment of the present invention.

FIG. 4 is a schematic diagram showing a gate driving circuit of a display according to a second embodiment of the present invention.

### DETAILED DESCRIPTION OF THE INVENTION

The following descriptions for the respective embodiments are specific embodiments capable of being implemented for illustrations of the present invention with referring to appended figures.

Certain terms are used throughout the description and following claims to refer to particular components. As one skilled in the art will appreciate, electronic equipment manufacturers may refer to a component by different names.

In the following description and claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one component is coupled to another component, that connection may be through a direct electrical connection, or through an indirect electrical connection via other components and connections. In addition, similar components are designated by the same reference numerals in the description and appending drawings.

In the present invention, the display can be implemented by a liquid crystal display (LCD) or an active-matrix liquid crystal display (AMLCD). The display comprises a display panel having pixels arranged in a matrix and a driving circuit utilized for driving the display panel. The driving circuit is divided into a source driving circuit and a gate driving circuit. The source driving circuit is utilized for transforming the inputted image data into data signals. Based on a sequence generated by a clock controller, the gate driving circuit will generate scan signals that are used to drive the pixels for displaying the image corresponding to the data signals.

The present invention puts emphasis on an improvement of the gate driving circuit for reducing current leakage caused by transistors inside the gate driving circuit, and thus improving the stability of the gate driving circuit, thereby improving image quality of the display panel. In addition, the solution provided in the present invention has better effects on preventing the transistors from occurring current leakage especially when the inner transistors of gate driving circuit are implemented by thin-film amorphous-Si transistors.

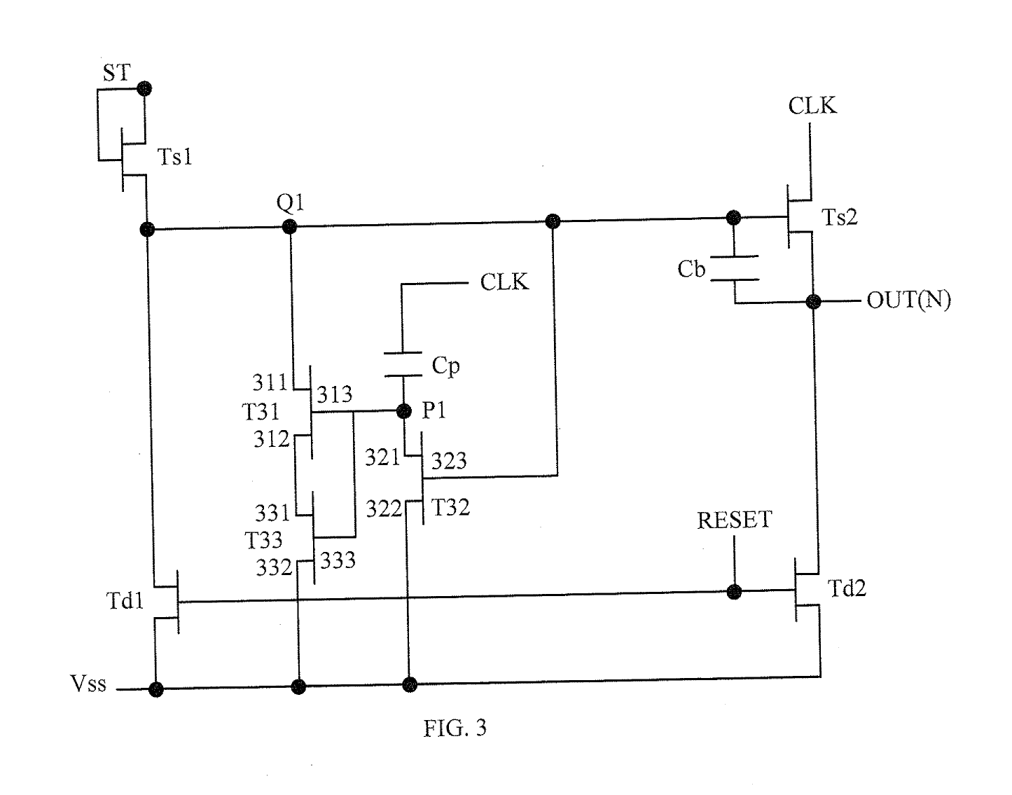

FIG. 3 is a schematic diagram showing a gate driving circuit of a display according to a first embodiment of the present invention. Although FIG. 3 merely illustrates one stage, a person skilled in the art understands that an integrated gate driving circuit is consisted of a plurality of circuit stages that are connected in series. Each stage correspondingly drives one or more gate lines in the display panel. The circuit of current stage not only provides a scan signal for a corresponding gate line but also provides an output signal as an input of a next-stage circuit.

As shown in FIG. 3, the gate driving circuit comprises a first transistor T31, a second transistor T32, a third transistor T33, and a capacitor Cp. An electrical connection between one end of the first transistor T31 and the second transistor T32 has a first node Q1 thereon. An electrical connection between another end of the first transistor T31 and the second transistor T32 has a second node P1 thereon.

Firstly, when a start signal ST is received, a high voltage level of the start signal ST will turn on a transistor Ts1 and then charge a storage capacitor Cb. When the charging process is completed and a clock signal CLK is at a high-voltage-level state, a transistor Ts2 is turned off and the storage capacitor Cb starts to discharge, and thus providing a voltage signal to a Nth gate line of the display panel. Said voltage signal serves as an output signal. OUT(N). In addition, when a transistor Td1 and a transistor Td2 are turned on by a reset signal TESET, the transistor Td1 may make the voltage of node Q1 be pulled down to a voltage closer to the voltage of a reference voltage signal Vss and the transistor Td2 may make the voltage of the output signal OUT(N) be pulled down to a voltage closer to the voltage of the reference voltage signal Vss. Meanwhile, the voltage outputted to the Nth gate line maintains a low level.

Specifically, the first node Q1 maintains a high voltage level in a period of time and maintains a low voltage level in another period of time based on the sequence of the start signal. When the first node Q1 is at the high voltage level, the storage capacitor Cb will be charged. The high voltage generated when discharging the storage capacitor Cb is inputted to the gate line corresponding to the circuit of current stage and serves as a scan signal for driving the pixels corresponding to the gate line of current stage.

In addition, when the start signal ST is at a low voltage level, the voltage of node Q1 may be slightly fluctuated due to affected by the voltage of the clock signal CLK. Therefore, it needs a noise suppressing circuit to avoid noise signals affecting the entire circuit. As shown in FIG. 3, when the voltage of start signal ST is at low level and the node Q1 is at slightly high voltage level due to affected by the clock signal CLK, the slightly high voltage level is insufficient to turn on the second transistor T32 but the high voltage of the clock signal CLK will turn on the first transistor T31 and the third transistor 133. In such a manner, the slightly high voltage level of the node Q1 will be pulled down to the reference voltage Vss, i.e., a ground potential.

Further, when the start signal ST is at a high voltage level, the high voltage of the node Q1 will turn on the second transistor T32 and the ground potential of the reference Vss will be conducted to the node P1. Ideally, the first transistor T31 and the third transistor T33 are now turned off, and thus the high voltage of the node Q1 is able to charge the storage capacitor Cb.

It needs a large current to drive the pixels corresponding to the gate line. That is to say, the voltage of the first node Q1 is required to be very high. This is easily to make the transistors (e.g., the first transistor T31) of the gate driving circuit generate leakage current. When the current leakage is occurred in the first transistor T31, the high voltage on the first node Q1 will be dropped as well. This causes a problem of insufficient driving voltage and makes the pixels corresponding to the gate line unable to function normally.

By connecting the first transistor T31 to at least one transistor (e.g., the third transistor T33) in series, the present invention can efficiently prevent the first transistor T31 from generating leakage current, and thereby efficiently solving the problem of stability of driving voltage of the gate driving circuit.

The arrangement of the gate driving circuit according to the first embodiment of the present invention will be detailedly described as follows.

The first transistor 31 is coupled between the first node Q1 and an input end of the reference voltage signal Vss. One end of the second transistor T32 is electrically connected to the first transistor T31 and another end of the second transistor T32 is electrically connected to the input end of the reference voltage signal Vss. Specifically, a first end 311 of the first transistor T31 is coupled to the first node Q1 and a second end 312 of the first transistor T31 is coupled to the input end of the reference voltage signal Vss. A second end 322 of the second transistor T32 is coupled to the input end of the reference voltage signal Vss and a third end 323 of the second transistor T32 is coupled to the first node Q1. A third end 313 of the first transistor T31 is electrically connected to a first end 321 of the second transistor T32. That is to say, in a specific arrangement, the gate electrode of the first transistor T31 is electrically connected to the source electrode or the drain electrode of the second transistor T32, and the gate electrode of the second transistor T32 is electrically connected to the first node Q1.

In the above amendment, when the first transistor T31 is turned on as well as the third transistor T33 is turned on, the voltage of the first node Q1 will be pulled down to a voltage closer to the voltage of the reference voltage signal Vss.

As described above, the first node Q1 will maintain a high voltage level in a period of time and maintain a low voltage level in another period of time based on the sequence of the start signal ST. By the charging and discharging process of the storage capacitor Cb, the high voltage level serves as a driving voltage for driving the pixels and the required voltage is quite high. When the first node Q1 is at a high-voltage-level state and the first transistor T31 is turned off, current leakage may be occurred in the first transistor T31 and thereby making the driving voltage on the first node Q1 to be insufficient. As to this, the technical scheme provided in the present invention to solve this problem will be detailedly described later.

A connecting terminal located between the first transistor 131 and the second transistor T32 has a second node P1 thereon. Specifically, the third end 313 of the first transistor T31 is electrically connected to the first end 321 of the second transistor T32 and forms the second node P1 therebetween. That is to say, in a specific arrangement, the connecting terminal located between the gate electrode of the first transistor T31 and the source/drain electrode of the second transistor T32 has the second node P1 thereon.

A capacitor Cp is disposed between the second node P1 and an input end of the clock signal CLK from the clock controller. Specifically, one end of the capacitor Cp is electrically connected to the second node P1 located between the first transistor T31 and the second transistor T31, and the other end of the capacitor Cp is electrically coupled to the input end of the clock signal CLK.

By inserting the coupled capacitor Cp between the second node P1 and the input end of the clock signal CLK, it can use less number of transistors for suppressing the noise signals that are generated due to high driving voltage in the gate driving circuit. Also, the slightly fluctuated voltage caused by the clock signal CLK is avoided for the node Q1. Therefore, the layout area of the gate driving circuit on the display panel can be reduced and this is quite beneficial to the development on narrow-border display products.

In the present invention, the gate driving circuit has at least one transistor, e.g., the third transistor T33 shown in FIG. 3, which is disposed between the first transistor T31 and the input end of the reference voltage signal Vss. The at least one transistor (or the third transistor T33) is connected to the first transistor T31 in series. Specifically, a first end 331 of the third transistor T33 is electrically connected to the second end 312 of the first transistor T31, a second end 332 of the third transistor T33 is electrically coupled to the input end of the reference voltage signal Vss, and a third end 333 of the third transistor T33 is electrically connected to the third end 313 of the first transistor T31. That is to say, in a specific arrangement, the gate electrode of the first transistor T31 is electrically connected to the gate electrode of the third transistor T33 such that the first transistor T31 and the third transistor T33 form a series circuit connection.

In the first embodiment of the present invention, the above-mentioned arrangement of the third transistor T33 makes the third transistor T33 and the first transistor T31 share the voltage difference between the first node Q1 and the input end of the reference voltage signal Vss. That is to say, the arrangement of the third transistor T33 can lighten the voltage load Vds between the source electrode and the drain electrode of the first transistor T31, thereby reducing the occurrence of current leakage in the first transistor T31.

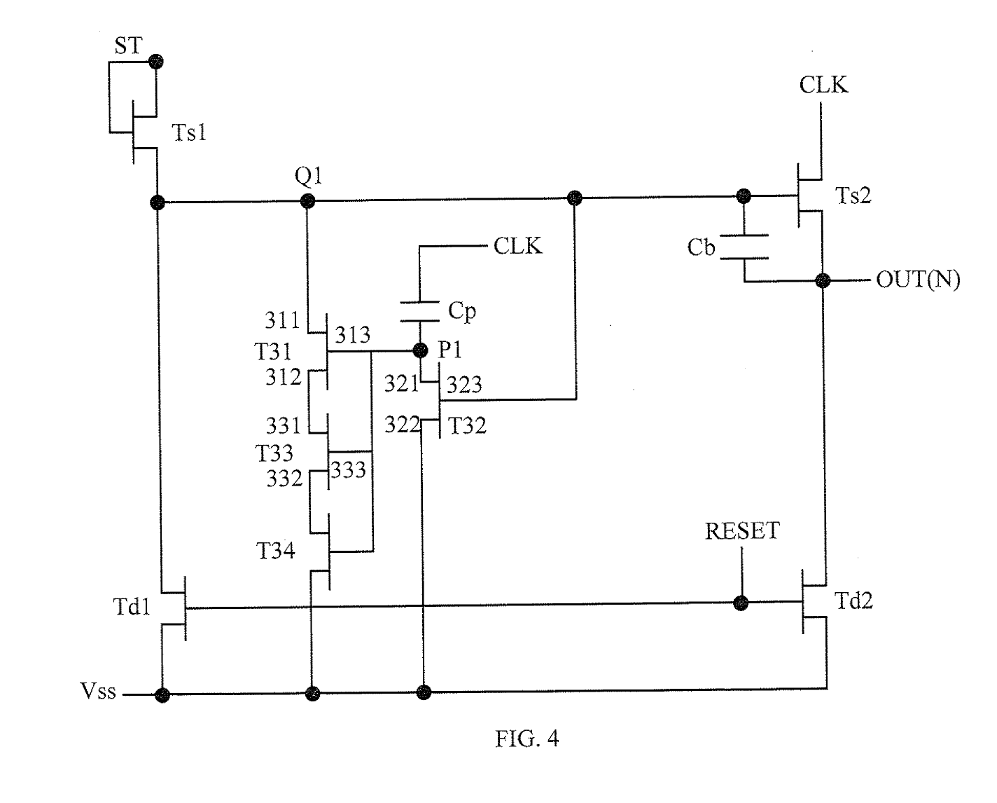

FIG. 4 is a schematic diagram showing a gate driving circuit of a display according to a second embodiment of the present invention. Compared to the first embodiment shown in FIG. 3, the gate driving circuit of the second embodiment shown in FIG. 4 further comprises a fourth transistor T34, which is disposed between the third transistor T33 and the input end of the reference voltage signal Vss. The fourth transistor T34 is connected to the third transistor T33 in series. In a specific arrangement, the gate electrode of the fourth transistor T34 is electrically connected to the gate electrode of the third transistor T33 such that the fourth transistor T34 and the third transistor T33 form a series circuit connection. Further, the first transistor T31, the third transistor T33, and the fourth transistor T34 are all connected in series.

In the second embodiment of the present invention, the above-mentioned arrangement of the fourth transistor T34 is added such that the third transistor T33 and the fourth transistor T34 can share the voltage difference between the first node Q1 and the input end of the reference voltage signal Vss with the first transistor T31. That is to say, the arrangement of the third transistor T33 and the fourth transistor T34 can lighten the voltage load Vds between the source electrode and the drain electrode of the first transistor T31, thereby reducing the occurrence of current leakage in the first transistor T31. Also, the arrangement of the present embodiment has two transistors, i.e., the third transistor T33 and the fourth transistor T34, and this has better effects on lightening the voltage load Vds between the source electrode and the gate electrode of the first transistor T31 and can effectively reduce the occurrence of current leakage in the first transistor T31, thereby assuring that the high voltage on the first node Q1 would not be affected.

By the above-mentioned embodiments of the present invention, it can be understood that the present invention can partly transfer the voltage load between the source electrode and the drain electrode of the first transistor to the at least one transistor (e.g., the third transistor and the fourth transistor) by connecting the at least one transistor in series between the first transistor and the input end of the reference voltage signal. In such a manner, when the first node is at a high-voltage-level state, the first transistor is unlikely to be affected so as to generate leakage current and make the voltage on the first node drop, lead to insufficient driving voltage. Therefore, the present invention can efficiently solve the problem of the stability of driving voltage of the gate driving circuit and improve the reliability of the gate driving circuit, thereby improving image quality of the display panel.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A gate driving circuit for a display, said circuit comprising:
a first node having a voltage level when a start signal passes the first node;
a first transistor coupled to the first node and an input end of a reference voltage signal, a voltage of the first node is pulled down to a voltage closer to the voltage of the reference voltage signal when the first transistor is turned on;
a second transistor, of which one end is electrically connected to the first transistor and another end is electrically connected to the input end of the reference voltage signal;
a second node located at a connecting terminal of the first transistor and the second transistor;
a capacitor disposed between the second node and an input end of a clock signal, the first transistor, the second transistor, and the capacitor are utilized to suppress noise signals; and
a third transistor disposed between the first transistor and the input end of the reference voltage signal, the third transistor is connected to the first transistor in series, the third transistor and the first transistor share a voltage difference between the first node and the input end of the reference voltage signal.

2. The gate driving circuit according to claim 1, wherein a gate electrode of the first transistor is electrically connected to a gate electrode of the third transistor.

3. The gate driving circuit according to claim 1, further comprising:
a fourth transistor disposed between the third transistor and the input end of the reference voltage signal, the fourth transistor is connected to the third transistor in series, the fourth transistor, the third transistor, and the first transistor share the voltage difference between the first node and the input end of the reference voltage signal.

4. The gate driving circuit according to claim 3, wherein a gate electrode of the third transistor is electrically connected to a gate electrode of the fourth transistor.

5. The gate driving circuit according to claim 1, wherein a gate electrode of the second transistor is electrically connected to the first node.

6. A gate driving circuit for a display, said circuit comprising:
a first transistor, a first end of the first transistor is coupled to a first node providing a high voltage level and a second end of the first transistor is coupled to an input end of a reference voltage signal;
a second transistor, a first end of the second transistor is electrically connected to a third end of the first transistor and forms a second node therebetween, a second end of the second transistor is coupled to the input end of the reference voltage signal and a third end of the second transistor is coupled to the first node;
a capacitor, of which one end is electrically connected to the second node located between the first transistor and the second transistor and the other end is electrically coupled to an input end of a clock signal; and
at least one transistor disposed between the first transistor and the input end of the reference voltage signal, the at least one transistor is connected to the first transistor in series.

7. The gate driving circuit according to claim 6, wherein the third end of the first transistor is a gate electrode and the gate electrode of the first transistor is electrically connected to the gate electrode of the at least one transistor.

8. The gate driving circuit according to claim 6, wherein a voltage of the first node is pulled down to a voltage closer to the voltage of the reference voltage signal when the first transistor and the at least one transistor are turned on.

9. The gate driving circuit according to claim 6, wherein the third end of the first transistor is a gate electrode and the first end of the second transistor is a source electrode or a drain electrode.

10. The gate driving circuit according to claim 6, wherein the first transistor, the second transistor, and the at least one transistor are amorphous-Si transistors.

11. A gate driving circuit for a display, said circuit comprising:
a first node for transmitting a driving signal of a high voltage level to an output terminal based on a start signal and a clock signal, the output terminal is electrically connected to a gate line;
a first transistor, a first end of the first transistor is coupled to the first node and a second end of the first transistor is coupled to an input end of a reference voltage signal;
a second transistor, a first end of the second transistor is electrically connected to a third end of the first transistor, a second end of the second transistor is coupled to the input end of the reference voltage signal, and a third end of the second transistor is coupled to the first node;
a second node located at a connecting terminal of the first transistor and the second transistor;
a capacitor, of which one end is electrically connected to the second node located between the first transistor and the second transistor and the other end is electrically coupled to an input end of the clock signal; and
at least one transistor disposed between the first transistor and the input end of the reference voltage signal, the at least one transistor is connected to the first transistor in series.

12. The gate driving circuit according to claim 11, further comprising:
a start transistor disposed between an input end of the start signal and the first node; and
a clock transistor disposed between the input end of the clock signal and the first node.

13. The gate driving circuit according to claim 11, further comprising:
a storage capacitor disposed between the first node and the output terminal.

14. The gate driving circuit according to claim 11, further comprising:
a first pull-down transistor disposed between the first node and the input end of the reference voltage signal; and
a second pull-down transistor disposed between the output terminal and the input end of the reference voltage signal, wherein voltages of the first node and the output terminal are pulled down to the voltage of the reference voltage signal when the first pull-down transistor and the second pull-down transistor are turned on according to a reset signal.
